(19) United States
(12) Patent Application Publication
(10) Pub. No.: US 2014/0083993 A1
(43) Pub. Date: Mar. 27, 2014

(54) PRINTED CIRCUIT BOARD FOR A DOMESTIC APPLIANCE, DOMESTIC APPLIANCE, AND A METHOD FOR OPERATING A DOMESTIC APPLIANCE

(71) Applicants: Thomas Maier, Garching a.d. Alz (DE); Stefan Schmal, Obersussbach (DE); Peter Schuhback, Holzhausen (DE)

(72) Inventors: Thomas Maier, Garching a.d. Alz (DE); Stefan Schmal, Obersussbach (DE); Peter Schuhback, Holzhausen (DE)

(73) Assignee: BSH BOSCH UND SIEMENS HAUSGERATE GMBH, Munich (DE)

(21) Appl. No.: 14/114,233

(22) PCT Filed: May 8, 2012
(86) PCT No.: PCT/EP12/58423

§ 371 Date: Oct. 28, 2013

(30) Foreign Application Priority Data
May 12, 2011 (DE) 10 2011 075 696.5

(51) Int. Cl. F24C 7/08; G01R 19/00; G01R 33/02

(52) U.S. Cl. CPC F24C 7/087; G01R 33/02; G01R 19/0092
USPC 219/446.1; 324/244

(57) ABSTRACT

A printed circuit board for a domestic appliance includes at least one conductive path which is provided on at least one of two sides of the printed board and adapted for supply with a load current. The printed circuit board has at least one magnetic field sensor which is configured and disposed to read a magnetic field that can be generated by the load current. The load current flowing through the at least one conductive path of the printed circuit board can be detected by contactless reading of the magnetic field generated by the load current through the at least one conductive path.

The invention relates to a printed circuit board for a domestic appliance, the printed circuit board having, on at least one of its two sides, at least one conductive path, to which a load current can be supplied. The invention also relates to a domestic appliance that has at least one such printed circuit board. The invention further relates to a method for operating an electrically operated domestic appliance having at least one printed circuit board.

Domestic appliances with electrical heating units are known, for example cookers, cooktops, etc., the heating units of which can be operated in a clocked manner with a load current. To this end a clock relay is incorporated in a load current path of the heating unit. The timing of the clock relay can typically be predefined by means of a control facility as a function of a setting of a power stage by a user. The relationship between the timing and the associated load current is determined beforehand by experiment or computation. However the problem arises here that the true strength of the load current cannot be detected. As a result it is not possible to identify for example sticking relays or breaks in the current path.

The object of the present invention is to resolve the problems of the prior art to some degree at least and in particular to provide a domestic appliance with improved operating safety.

This object is achieved according to the features of the independent claims. Preferred embodiments will emerge in particular from the dependent claims.

The object is achieved by a printed circuit board for a domestic appliance, wherein the printed circuit board, on at least one of its two sides, has at least one conductive path to which a load current can be applied and the printed circuit board has at least one magnetic field sensor, which is set up and disposed to read a magnetic field that can be generated by means of the load current (flowing through the at least one conductive path).

A load current can refer in particular to a current, which is relatively large compared with other currents on the printed circuit board (signal currents, etc.). A load current can also refer in particular to a current, which is used to operate a consumer connected to the printed circuit board. A load current can also refer to a current, which is assigned to a low voltage above an extra-low voltage, e.g. is generated thereby, for example a network voltage. Non-load currents can be assigned in particular to an extra-low voltage, e.g. be generated thereby. The extra-low voltage can be in particular an extra-low voltage for safety purposes, an extra-low voltage for protection purposes, an extra-low voltage for functional purposes or an operating voltage for electronic circuits.

A magnetic field sensor can refer in particular to a sensor, which can detect effects of the magnetic field on magnetically hard and/or magnetically soft materials or other solid bodies (semiconductors, resistance layers). The magnetic field sensor can be understood in particular to be a general current sensor, which can read or measure a current strength in the at least one load current-carrying conductive path contactlessly based on its magnetic field. In particular a magnetic field sensor cannot be a sensor, which has to be integrated at least partially in the load current-carrying, readable conductive path, for example having a coil that is integrated in the conductive path and therefore connected in series.

This printed circuit board has the advantage that dedicated current sensors (e.g. coils and the like) do not have to be incorporated in the readable conductive path(s) to which a load current can be supplied. The load current (presence, size, etc.) can instead be determined contactlessly by way of the magnetic field generated per se by the load current in the conductive path. In particular this only requires a small amount of adaptation when integrating the magnetic field sensor in existing board layouts. It is possible to monitor at least one current path carried by way of the at least one conductive path by means of the magnetic field sensor or the contactless current sensor. It is thus possible in particular to identify defective components in the power circuit reliably, for example a defective heating unit, a stuck relay, a conductive path break, etc. (self-diagnosis). Easily implementable current regulation is also possible.

In one development the magnetic field sensor is a magnetic field sensor based on the galvanomagnetic effect.

In one embodiment the magnetic field sensor is a Hall sensor. The Hall sensor has the advantage that it is compact, robust and yet also sensitive in respect of measuring.

Alternatively the magnetic field sensor can be for example an AMR (anisotropic magnetoresistive effect) sensor, a GMR or giant magnetoresistance sensor, a CMR (colossal magnetoresistive effect) sensor, a TMR (magnetic tunnel resistance) sensor, a SQUID sensor or the like.

In another embodiment the at least one magnetic field sensor is disposed on a side of the printed circuit board facing away from the conductive path to be read. This isolates the magnetic field sensor galvanically from the readable, load current-carrying conductive path, in particular because a printed circuit board typically insulates its two sides electrically from one another. This allows simple isolation of the magnetic field sensor in terms of voltage from the at least one load current-carrying printed circuit board. The printed circuit board is in particular magnetically permeable for this purpose.

The printed circuit board can be fitted on one side or two. If it is fitted on one side, the at least one load current-carrying conductive path preferably runs on the side facing away from the fitted side, with the result that creepage distances can be relatively large. Fitting on two sides allows particularly simple and effective voltage-related isolation of the two sides of the printed circuit board into a primary side or high-voltage side and a secondary side or low-voltage side.

In a further embodiment the at least one magnetic field sensor comprises at least one analog magnetic field sensor. An analog magnetic field sensor can refer in particular to a magnetic field sensor, the output signal or sensor signal of which is constant, in particular proportional, in relation to the read magnetic field, in particular its magnetic field strength. An analog magnetic field sensor has the advantage that it can be used to determine a current strength and/or change in a current strength of the load current in the at least one read conductive path quantitatively, for example by way of a calculation algorithm or one or more characteristic lines which link the output signal to a current strength. The analog magnetic field sensor can be implemented by means of a Hall sensor for example. At a Hall sensor it is possible to tap an output signal, the amplitude of which is proportional to the current in the read conductive path.

In a further embodiment the analog magnetic field sensor, in particular Hall sensor, reads a superimposed magnetic field from two conductive paths, the conductive paths representing different external conductors of a shared power line. As external conductors the two conductive paths therefore carry different phases of a three-phase current flowing in the shared power line. The analog magnetic field sensor can therefore in particular read a magnetic field that is superimposed from magnetic fields from the individual conductive paths that are of essentially identical strength but have a phase offset. This facilitates a quantitative determination of the current strength and/or any change thereto, in particular if only two external conductors are required for a current supply to a specific consumer.

In a further embodiment the analog magnetic field sensor, in particular Hall sensor, is disposed between the two conductive paths. This embodiment has the advantage that the relative strength of the magnetic fields generated by the two conductive paths is essentially identical. To this end the two conductive paths can run in particular in a parallel manner in the region of the magnetic field sensor. The magnetic field sensor may in particular be disposed in the center between the two conductive paths (when viewed from above), for which a Hall sensor is particularly suitable, as it demonstrates the greatest sensitivity when offset in relation to the conductive path.

In a further embodiment the at least one magnetic field sensor comprises at least one digital magnetic field sensor. A digital magnetic field sensor can refer in particular to a magnetic field sensor, the output signal of which changes abruptly as the magnetic field strength changes, in particular when a predetermined magnetic field strength threshold value is reached. Such a magnetic field sensor can be particularly simple and economical and can in particular provide knowledge about the presence of a load current in the at least one conductive path from a defined current strength. The digital magnetic field sensor is particularly suitable for monitoring current in respect of safety requirements. The digital magnetic field sensor is for example suitable for monitoring the presence of a current flow in a main switch current path of an electrically operated domestic appliance. The digital magnetic field sensor can be for example a Hall sensor, an AMR sensor, etc.

In a general development one (analog or digital) magnetic field sensor is disposed between two or more conductive paths. The magnetic field sensor can thus read the current of the two or more conductive paths or can monitor or evaluate two or more conductive paths at the same time. The distance between two adjacent, in particular parallel, conductive paths or conductive path segments can be preferably 2 to 4 mm. The magnetic field sensor may be disposed on the same side of the printed circuit board as the conductive path to be read but does not have to be.

The magnetic field sensor can be disposed so that it is laterally offset in relation to a conductive path to be read or monitored (from the same side or the side facing away therefrom) or can be disposed on the side of the printed circuit board facing away directly above the conductive path.

In one development the at least one readable conductive path is connected electrically to at least one consumer. In one embodiment the at least one readable conductive path is connected to at least one connection element disposed on the printed circuit board for the connection of at least one consumer. The connection element can be in particular a plug-in connector, e.g. a plug.

In a further embodiment a readable conductive path can be supplied with load current for just one consumer. It is thus possible to determine or monitor a current strength in relation to this one consumer. This allows particularly precise and individual operation of said consumer.

In a further embodiment a readable conductive path is a busbar path which can be supplied with current for a number of consumers. This allows current strength to be determined or monitored in relation to this number of consumers. This allows simple safety monitoring of the domestic appliance. The busbar path can carry a main switch current for example.

The object is also achieved by a domestic appliance, the domestic appliance having at least one printed circuit board as described above. The domestic appliance can have the same embodiments and advantages as the printed circuit board. It is also possible to enhance the operating safety of the domestic appliance.

In one embodiment for example the domestic appliance has at least one printed circuit board, on which the at least one readable conductive path is connected to at least one connection element disposed on the printed circuit board for the connection of at least one consumer and at least one readable conductive path of the printed circuit board is connected electrically to at least one consumer.

In a further embodiment the at least one consumer comprises at least one heating element or heating unit. The associated domestic appliance can then be in particular an electrically operated cooking appliance (cooktop, oven, cooker, etc.) However the printed circuit board and associated domestic appliance are not limited thereto. Therefore the consumer may also be a refrigeration unit of a refrigerator, a heater of a laundry treatment appliance (washing machine, tumble dryer, etc.), a heating element of a toaster, electric kettle or other small domestic appliance, etc.

A domestic appliance may have one or more consumers, e.g. different heating elements, connected to a printed circuit board.

The domestic appliance may in particular have a control facility, for example disposed on the printed circuit board, which is coupled functionally to the at least one magnetic field sensor. The control facility may be set up to determine a load current based on an output signal or sensor signal of the at least one magnetic field sensor. The control facility can also be set up to regulate a load current of at least one consumer based on an output signal or sensor signal or a value derived therefrom (e.g. a load current strength) of at least one magnetic field sensor, which is assigned to at least one conductive path carrying load current for said consumer.

The domestic appliance may in particular be set up, for example by means of the control facility, to detect a failure of a consumer or its power circuit by means of the strength of a load current flowing through said consumer as determined using the at least one magnetic field sensor.

For example the consumer, in particular a heating element, may be operated in a clocked manner by means of a relay. If the relay sticks, it remains incorrectly in one position, for example the opened position or the closed position. In the opened position no current flows through the consumer despite a power stage set by a user by way of example. In the closed position a load current flows through the consumer despite the relay being deactivated. The at least one magnetic field sensor allows the control unit to compare an actual value for a load current of a defined consumer with an associated setpoint value, triggering at least one corresponding action. For example, if the actual value is too low, e.g. if a relay is stuck in the open position, a conductive path is broken, a consumer is defective, etc., a first warning message can be output. Alternatively or additionally if the actual value is too high, e.g. if a relay is stuck in the closed position, a second warning message can be output for example and/or the domestic appliance can be switched off.

The domestic appliance can be set up in particular to perform a self-diagnosis or self-test after being switched on. To this end an actual value of a load current of a respective consumer can be compared with an associated setpoint value.

The self-test can alternatively or additionally be performed by means of a digital magnetic field sensor. To this end the digital magnetic field sensor may in particular read a magnetic field of a main switch current path.

If for example after switching on and/or during the course of switching off the domestic appliance, when no consumer is operated in respect of power on the user side, the current strength for example is above a predetermined threshold value, this may be an indication of a relay stuck in the closed state or the like and the domestic appliance can respond to this accordingly (switching off, outputting a warning message, etc.). To this end the digital magnetic field sensor can output a signal when a predetermined threshold value of a magnetic field strength is reached or exceeded. The threshold value can in particular be selected so that a non-power current, e.g. a current consumed by electronic components, lamps, display units, etc., does not reach the threshold value.

Even if all the consumers are operated in a predefined manner, in particular a manner predetermined by the domestic appliance, in respect of power (optionally at a low stage), the value may be below a predetermined threshold value. This may indicate a relay stuck in the open position, a break in the conductive path or the like and the domestic appliance can respond to this accordingly (outputting a warning message, etc.). For example the conductive paths to which load current can be supplied can be switched to all-pole, in particular automatically by the domestic appliance for the purposes of self-diagnosis.

In a further embodiment the domestic appliance, in particular its control facility, is set up to determine an energy consumption from the output signal or sensor signal of the at least one, in particular analog, magnetic field sensor. The energy consumption can be an energy consumption accumulated over time and/or a power. This can be performed for the entire appliance (load-related overall energy consumption) and/or for selected consumers, e.g. for individual hotplates of a cooktop. The energy consumption can be displayed on the domestic appliance. Alternatively the energy consumption, in particular the overall energy consumption, can be used as an input variable for energy management of the domestic appliance.

The overall energy consumption, in particular an overall power, can also be monitored to determine whether it reaches or exceeds a maximum value, in particular for a power limit. Reaching or exceeding such a maximum can trigger an action, e.g. a power reduction or the switching off of certain consumers, the outputting of a warning message, etc. The overall energy consumption can be determined in particular by means of at least one analog or digital magnetic field sensor, which monitors a main switch current path. The main switch current path can be carried on one or more conductive paths. The main switch current path can in particular be carried through a single main switch or main switch relay.

The object is also achieved by a method for operating an electrically operated domestic appliance with at least one printed circuit board, wherein a load current flowing through at least one conductive path of the printed circuit board is detected. With the method the load current is also detected by the contactless reading of a magnetic field that can be generated by means of the load current through the at least one conductive path.

The method can be embodied in the same manner as the printed circuit board or domestic appliance and has corresponding advantages.

The invention is described schematically in more detail in the figures below based on exemplary embodiments. Identical elements or those with identical effect can be shown with the same reference characters here for greater clarity.

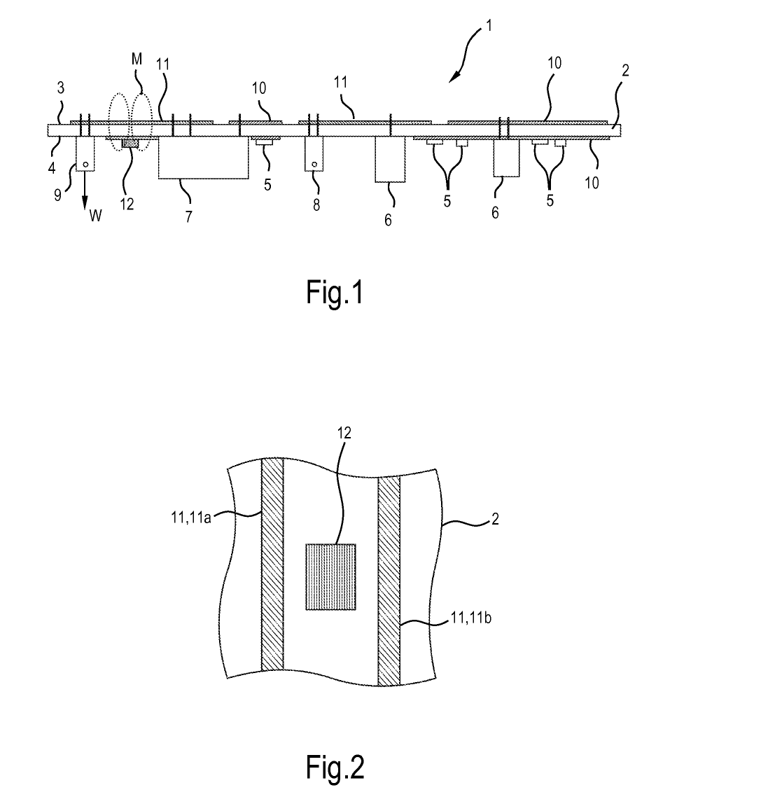

FIG. 1 shows a sectional diagram in the form of a side view of an inventive printed circuit board according to a first embodiment;

FIG. 2 shows a plan view of an arrangement of two load current-carrying conductive paths with an associated magnetic field sensor;

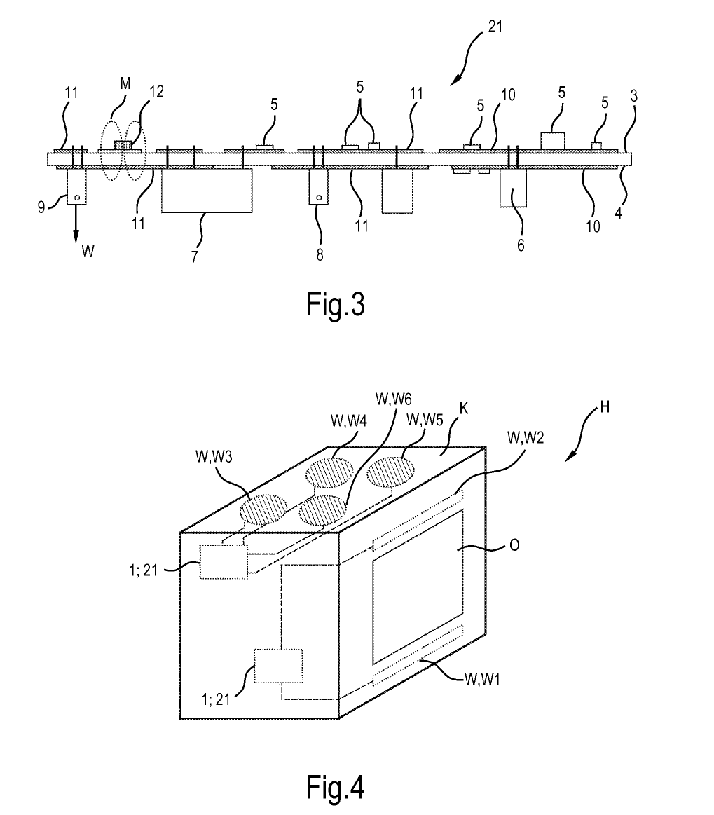

FIG. 3 shows a sectional diagram in the form of a side view of an inventive printed circuit board according to a second embodiment; and

FIG. 4 shows a domestic appliance with two inventive printed circuit boards.

FIG. 1 shows a printed circuit board 1 according to a first embodiment. The printed circuit board 1 has a plate-type substrate 2 with a first side 3 and a second side 4 opposite thereto. The printed circuit board 2 insulates the two sides 3, 4 electrically from one another. The printed circuit board 2 is fitted on one side, in this instance on the second (lower) side 4. The printed circuit board 2 here is fitted by way of example with electrical or electronic SMD components 5, e.g. resistors, capacitors, etc., and with power components such as power capacitors 6, a relay 7, plugs 8, 9 and a transformer (not shown). One of the plugs 8 is used for connection to a network connection and another of the plugs 9 is used for connecting a consumer W (see FIG. 4).

The printed circuit board 1 is wired on both sides, the wiring of the fitted second side 4 comprising conductive paths 10, which are provided as signal and activation lines and are supplied with a low voltage. The wiring of the first, non-fitted, side 3 also comprises load current-carrying conductive paths 11, at which the network voltage is present. The spatial isolation of the conductive paths 10, 11 by means of the electrically insulating substrate 2 enhances operating safety and allows creepage distances and air gaps in particular to be complied with in a simple manner.

The consumer connected to the plug 9 is operated with a network voltage that is clocked by way of the relay 7. The consumer may in particular be operated in a multiphase manner so that it can be connected to a number of (in particular two or three) external conductors. The external conductors can be configured in particular as isolated conductive paths 11.

In order to be able to monitor a current (current strength or the like) through the consumer, a magnetic field sensor 12 is disposed on the second side 4 of the printed circuit board 1. The magnetic field sensor 12 is set up and disposed to read a magnetic field M generated by at least one load current-carrying conductive path 11, which supplies said consumer or is connected electrically thereto. The magnetic field sensor 12 is configured as an “analog” magnetic field sensor 12, which is able to output an output signal or sensor signal that is proportional to a strength of the magnetic field M and therefore to a current strength in the read conductive path 11. The output signal can be evaluated or further processed by means of a control facility, which is also implemented on the printed circuit board 1 or alternatively for example on a dedicated control board.

The magnetic field sensor 12 is able in particular to determine a current strength though the consumer quantitatively. Knowledge of the current strength can be used for example to regulate the current to the consumer, to display consumption, e.g. of a current power or a power consumption accumulated over time, to limit power, to check safety, e.g. as part of a self-test, e.g. to check for a stuck relay 7, a broken conductive path 11, etc.

FIG. 2 shows a plan view of a possible arrangement of two load current-carrying conductive paths 11, specifically conductive paths 11a and 11b, in relation to an associated magnetic field sensor 12 of the printed circuit board 1. The sections of the conductive paths 11a, 11b shown are disposed parallel in segments at least at a distance of between 2 mm and 4 mm on the first side 3 and are both connected to the plug 9. The conductive paths 11a and 11b are embodied as external conductors for supplying a consumer (not shown) connected to the plug 9 and to this end each carry load currents (with a phase offset of 120° to one another) or three-phase current phases, in this instance of a network current. The consumer is therefore supplied with current (in a clocked manner) over at least two phases of a network supply. The magnetic fields generated by the phase-offset currents in the conductive paths 11a, 11b are correspondingly phase-offset or time-offset. These magnetic fields are superimposed, their magnetic field strength reaching an essentially identical maximum value between the two conductive paths 11a, 11b. The magnetic fields therefore have an identical relative strength between the two conductive paths 11a, 11b.

The magnetic field sensor 12 is disposed on the second side 4 and when viewed from above is disposed precisely in the center between the two conductive paths 11a, 11b positioned on the first side 3 (or the illustrated parallel segments thereof). As the Hall sensor used demonstrates its maximum sensitivity when offset laterally in relation to a conductive path 11 to be read, a magnetic field can be read with a high level of sensitivity at the (Hall) magnetic field sensor 12, said magnetic field corresponding to a superimposition of the magnetic fields of the two conductive paths 11a, 11b with identical strength. The output signal of the magnetic field sensor 12 is therefore proportional to the added currents in the conductive paths 11a and 11b. This output signal is particularly simple to evaluate, particularly if the consumer is only operated by means of two phases.

FIG. 3 shows a sectional diagram in the form of a side view of an inventive printed circuit board 21 according to a second embodiment. The printed circuit board 21 has a similar structure to the printed circuit board 1 but is now fitted on both sides. The low-voltage components, such as the electrical or electronic SMD components 5 and the magnetic field sensor 12, are disposed on the first side 3 here. Network voltage components, such as the power capacitors 6, the relay 7 and the plugs 8, 9, which are connected in particular to the network voltage, are positioned on the second side 4. This improves the isolation of the two voltage regions.

FIG. 4 shows a domestic appliance H with two inventive printed circuit boards 1; 21. The domestic appliance H is configured as a cooker with an integrated oven O and cooktop K. The oven O has a number of consumers in the form of heating units W, specifically a bottom heat heating unit W1 and a top heat heating unit W1. For power supply purposes said heating units W1, W2 are connected electrically to a first printed circuit board 1 or 21, namely by way of respective plugs 9, and can be clocked by way of respective relays 7. The cooktop K has four hotplates, which can be heated by means of a respective resistance heating unit W3-W6. The resistance heating units W3 to W6 are connected electrically to a second printed circuit board 1 or 21, namely by way of respective plugs 9, and can be clocked by way of respective relays 7.

The domestic appliance H may have a single main switch current path both for the oven O (which carries the load currents for the heating units W1 and W2) and for the cooktop K (which carries the load currents for the heating units W3 to W6), or alternatively one main switch current path for the oven O and one for the cooktop K. The (at least one) main switch current path may (in each instance) be monitored by means of a further magnetic field sensor (not shown), for example for power limiting and/or for self-diagnosis to enhance operating safety.

The present invention is of course not limited to the illustrated exemplary embodiments.

Other phase angles are also possible, for example 180°.

Also the distance between parallel conductive paths to be read can be more or less than 2 to 4 mm.

### LIST OF REFERENCE CHARACTERS

1 Printed circuit board
2 Substrate
3 First side of substrate
4 Second side of substrate
5 SMD component
6 Power capacitor
7 Relay
8 Plug
9 Plug
10 Non-load current-carrying conductive path
11 Load current-carrying conductive path
11a Conductive path
11b Conductive path
12 Magnetic field sensor
21 Printed circuit board
H Domestic appliance
K Cooktop
M Magnetic field
O Oven
W Heating unit

1-13. (canceled)

14. A printed circuit board for a domestic appliance, said printed circuit board comprising:
at least one conductive path provided on at least one of two sides of the printed board and adapted for supply with a load current, and
at least one magnetic field sensor configured and disposed to read a magnetic field that can be generated by the load current.

15. The printed circuit board of claim 14, wherein the magnetic field sensor is a magnetic field sensor based on a galvanomagnetic effect.

16. The printed circuit board of claim 14, wherein the magnetic field sensor is a Hall sensor.

17. The printed circuit board of claim 14, wherein the at least one magnetic field sensor comprises at least one analog magnetic field sensor.

18. The printed circuit board of claim 17, wherein the analog magnetic field sensor reads a superimposed magnetic field from two of said conductive path, with the conductive paths representing different external conductors of a shared power line.

19. The printed circuit board of claim 17, wherein the analog magnetic field sensor is a Hall sensor.

20. The printed circuit board of claim 18, wherein the analog magnetic field sensor is disposed between the two conductive paths.

21. The printed circuit board of claim 14, wherein the at least one magnetic field sensor comprises at least one digital magnetic field sensor.

22. The printed circuit board of claim 14, wherein the at least one magnetic field sensor is disposed on a side of the printed circuit board facing away from the conductive path to be read.

23. The printed circuit board of claim 14, further comprising at least one connection element disposed on the printed circuit board for connection of the at least one conductive path to at least one consumer.

24. The printed circuit board of claim 14, wherein the at least one conductive path is a readable conductive path which can be supplied with load current for just one consumer.

25. The printed circuit board of claim 14, wherein the at least one conductive path is a readable conductive path which is a busbar path configured for supply with current for a number of consumers.

26. A domestic appliance, comprising at least one printed circuit board having at least one readable conductive path provided on at least one of two sides of the printed board and adapted for supply with a load current, at least one magnetic field sensor configured and disposed to read a magnetic field that can be generated by the load current, and at least one connection element disposed on the printed circuit board for connection of the at least one readable conductive path to at least one consumer.

27. The domestic appliance of claim 26, constructed in the form of a cooking appliance.

28. The domestic appliance of claim 26, wherein the at least one consumer comprises at least one heating element.

29. A method for operating an electrically operated domestic appliance with at least one printed circuit board, said method comprising detecting a load current flowing through at least one conductive path of the printed circuit board by contactless reading of a magnetic field that can be generated by the load current through the at least one conductive path.
